(19) United States
(12) Patent Application Publication
(10) Pub. No.: US 2014/0023996 A1
(43) Pub. Date: Jan. 23, 2014

(54) Three Dimensional Model Objects

(71) Applicants: Sean Finn, Benicia, CA (US); Mike Heitman, Walnut Creek, CA (US)

(72) Inventors: Sean Finn, Benicia, CA (US); Mike Heitman, Walnut Creek, CA (US)

(73) Assignee: F3 & Associates, Inc., Benicia, CA (US)

(21) Appl. No.: 13/551,618

(22) Filed: Jul. 18, 2012

(51) Int. Cl. G09B 25/00; C23C 16/52; B05D 1/36

(52) U.S. Cl. 434/72; 428/15; 427/258; 427/8

(57) ABSTRACT

Embodiments of the present invention provide a three dimensional model object, a method of producing the three dimensional model object, and a kit comprising the three dimensional model object and a scaled measurement device. The method in accordance with the present invention includes surveying a constructed structure which is georeferenceable in the real world, obtaining spatial data associated with the constructed structure, generating a digital three dimensional model of the constructed structure in a computer, and producing a physical model object with accurately surveyed as-built data of the constructed structure. The physical model object of the constructed structure can incorporate, on its surface, surveyed and measured useful real world intelligence, such as dimensions, georeference data, or orientation, associated with the constructed structure.

### BACKGROUND OF THE INVENTION

Buildings, industrial plants, infrastructures, and other constructed structures are surveyed by professional surveyors for a variety of reasons. As an example, a portion or the entire constructed structures may need to be renovated, restored, modified, or replaced. Constructed structures may be surveyed for other reasons, such as safety or archiving purposes. Constructed structures can be large or complicated in their physical features. Thus, it is useful to have accurate as-built data of a constructed structure prior to planning a future project, particularly when the existing constructed structure needs to be renovated, restored, or modified.

Professional surveyors use various surveying instruments to collect as-built data associated with a constructed structure to determine its shape, contour, orientation, and dimensions of various features. After surveying of the constructed structure, professional surveyors present, to engineers and other building professionals, a two dimensional paper plan of the constructed structure or virtual models generated by a computer as deliverables. While presentations in these formats are useful in planning a future project for the surveyed constructed structure, there is a need to improve the presentation of the surveyed data for better visualization and function in planning a future project. The present invention meets these and other needs.

### SUMMARY OF THE INVENTION

Embodiments of the present invention relates generally to a method of producing a three dimensional (“3D”) model object based on spatial data obtained by surveying a constructed structure in the real world and the 3D model object produced by the method. More specifically, the present invention relates to a method of producing a physical 3D model object based on accurately surveyed spatial data using a 3D printer. Therefore, the 3D model object produced in accordance with the present invention represents a scaled down version of a constructed structure which is produced using accurately surveyed as-built data of the constructed structure. The physical 3D model object in accordance with the present invention can also include, on its surface, useful, relevant, and measured real-world intelligence, such as dimensions or georeference data, associated with the constructed structure. The methods and techniques can be applied to a variety of projects, such as renovating, restoring, replacing, modifying, or archiving constructed structures.

In one aspect of the present invention, a method of producing a 3D model object is provided. The method includes entering, into a processor of a 3D printer, image data comprising a digital 3D model of a constructed structure wherein the digital 3D model was generated based on spatial data obtained by surveying the constructed structure. The constructed structure is georeferenceable in a real-world coordinate system and an elevation datum. The methods also includes producing a 3D model object of the constructed structure, using a 3D printer, at a calculated scaled down ratio compared to the constructed structure based on the image data.

In one embodiment, the method includes surveying a constructed structure to obtain spatial data associated with the constructed structure, and generating image data comprising a digital 3D model of the constructed structure based on the spatial data. In one implementation, a 3D laser scanner is used to obtain spatial data.

In another embodiment, the method includes transmitting image data comprising a digital 3D model to produce a 3D model object of the constructed structure at a predetermined scaled down ratio compared to the constructed structure based on the image data.

In yet another embodiment, the method further includes georeferencing the spatial data to at least one of a real-world coordinate system and an elevation datum and determining one or more georeference parameters associated with at least a portion of the constructed structure in relation to at least one of the real-world coordinate system or the elevation datum. The method further includes modifying the image data comprising the digital 3D model of the constructed structure by incorporating one or more georeference markings representing the one or more georeference parameters associated with the at least a portion of the constructed structure.

In yet another embodiment, the method further includes determining one or more geometric parameters associated with at least a portion of the constructed structure using the spatial data, and modifying the image data comprising the digital 3D model of the constructed structure by incorporating one or more geometric markings representing the one or more geometric parameters associated with the at least a portion of the constructed structure.

According to another aspect of the present invention, a 3D model object produced by methods in accordance with the present invention is provided.

According to another aspect of the present invention, a kit is provided. A kit includes a 3D model object produced by methods described herein and a scaled measurement device which has distance markings indicating a scale of a 3D model object in relation to the constructed structure.

These and other embodiments of the invention along with many of its advantages and features are described in more detail in conjunction with the text below and attached figures.

### BRIEF DESCRIPTION OF THE DRAWINGS

FIG. 1 is a high level schematic diagram illustrating an interaction of a surveying device, a user computer, and a 3D printer according to an embodiment of the present invention.

FIG. 2 is a high level flowchart illustrating a method of producing a 3D model object of a constructed structure based on as-built spatial data obtained by surveying according to an embodiment of the present invention.

FIG. 3 is a high level flowchart illustrating a method of producing a 3D model object with georeference markings incorporated therein according to one embodiment of the present invention.

FIG. 4A illustrates an exemplary 3D model object representing a coker unit according to an embodiment of the present invention.

FIGS. 4B and 4C illustrate exemplary 3D model object pieces representing sections of a coker unit according to an embodiment of the present invention.

FIGS. 5A and 5B illustrate exemplary scaled measurement devices that can be used to measure dimensions on 3D model objects according to an embodiment of the present invention.

### DETAILED DESCRIPTION OF SPECIFIC EMBODIMENTS

Embodiments of the present invention provide a 3D model object which is a scaled down reproduction of a real-world constructed structure based on accurately surveyed data and a method of producing the 3D model object. The 3D model object in accordance with the present invention is not based on a conceptual design. Rather, it is based on accurately surveyed and measured spatial data associated with a real-world constructed structure.

When a constructed structure, such as a building, an industrial plant, infrastructure, or any structural elements thereof, needs to be renovated or replaced, obtaining accurate as-built data is desirable in the project planning and designing process. The accurate as-built data is particularly desirable where a portion of the existing constructed structure needs to be preserved while other portions need to be renovated or restored. Many older buildings or industrial plants are over thirty years old, and hardcopy blueprints or other as-built data are not readily available. Even when the original blueprints are available, a constructed structure may have been upgraded over time and the original blueprints may not accurately reflect the current features of the constructed structure. As such, obtaining accurate as-built data is typically a first step in planning renovation, restoration, or replacement projects.

In embodiments of the present invention, as-built data of a constructed structure can be obtained using various surveying techniques. As used herein, as-built data refers to data related to horizontal and vertical locations of features in the constructed structure. As used herein, surveying refers to examining a constructed structure and obtaining spatial data to accurately determine a three dimensional position of points (of physical features on the surface of the constructed structure) and the distances and angles between them. Through surveying, various orientation, positional, and dimensional relationships (e.g., distances) among points, lines, and physical features on or near the surface of a constructed structure can be determined.

In one implementation, a 3D laser scanning device can be used to determine as-built data or spatial data of a constructed structure. A laser scanning device scans a real-world constructed structure and generates spatial data or scan data in the form of a point cloud, each point indicating a location of a corresponding point on a surface of the constructed structure. The point cloud data can be analyzed to obtain information related to surface contour, geometric data, color, texture, orientation, georeference data, or other attribute information related to the surveyed constructed structures. In other embodiments, traditional surveying instruments, such as a theodolite or a total station, can be used alone or in combination with a 3D laser scanning device for spatial data acquisition.

After obtaining the spatial data, the spatial data can be used to create a digital 3D model of the constructed structure. A digital 3D model refers to a three dimensional representation of a constructed structure in a digital format which can be viewed on a computer screen or other electronic devices. A digital 3D model is generated by modeling software, such as computer-aided design (CAD) software. In some embodiments, the digital 3D model of the constructed structure can be modified by incorporating relevant and measured real-world intelligence associated with the constructed structure. The real-world intelligence may include georeference information, such as geographic coordinates, an elevation datum, or other objective positional information associated with at least a portion of the constructed structure. Alternatively or additionally, the real-world intelligence associated with the constructed structure may include dimensions or other geometric data associated with the constructed structure.

Based on the digital 3D model generated by modeling software, a 3D model object is produced using a 3D printer. The 3D model object is a physical object that can be touched and manipulated by hands in the real world. Since the digital 3D model is based on accurately surveyed data, the 3D model object is a physical object which is a precise, scaled down reproduction of the real-world constructed structure. Thus, the 3D model object is constructed using accurately surveyed spatial data associated with the constructed structure. In some embodiments, a 3D model object has, on its surface, markings representing relevant, useful, and measured real-world intelligence associated with the constructed structure. Such a 3D model object can be used by engineers and other building professionals to discuss future project designs and plans.

Embodiments of the present invention provide several advantages over two dimensional (“2D”) hard copy drawings or computer generated virtual models. A 3D model object is a physical object that can be touched and manipulated by hands of building professionals. Thus, a 3D model object of a constructed structure provides a physically touchable visual aid which embodies accurate as-built data of the constructed structure. Multiple parties involved in planning future renovation or replacement of a constructed structure can physically touch and manipulate the 3D model object in a meeting to further discuss any additional design modifications or future project plans. Furthermore, surveyed and measured real-world intelligence incorporated on the surface of a 3D model object allows building professionals to better visualize positioning and orientation of the 3D model object in the field. By providing accurate as-built data in the form of physical 3D model objects at an early stage of design or development, an owner of a constructed structure can save time and cost in planning a future project.

Furthermore, while 3D model object prototypes or 3D conceptual model objects based on conceptual designs (e.g., an architecture drawing) do exist, they are not produced using accurately surveyed and measured geometric and georeference data of a constructed structure. In embodiments of the present invention, the surveyed geometric and/or georeference parameters of a constructed structure are generally within ⅛ of an inch of actual parameters with at least a 95 percent confidence level. By using such highly accurately surveyed parameters to construct a 3D model object, a 3D model object in accordance with embodiments of the present invention can be a highly accurate representation of a constructed structure. For a modification or replacement project that involves a large constructed structure, slight errors in measurements can be quite costly. As such, it is desirable to have a highly accurate 3D model object, especially when the 3D model object needs to be accurately represented in terms of its orientation or position with respect to the earth.

Examples of embodiments of the present invention are illustrated using figures and are described below. The figures described herein are used to illustrate embodiments of the present invention, and are not in any way intended to limit the scope of the invention.

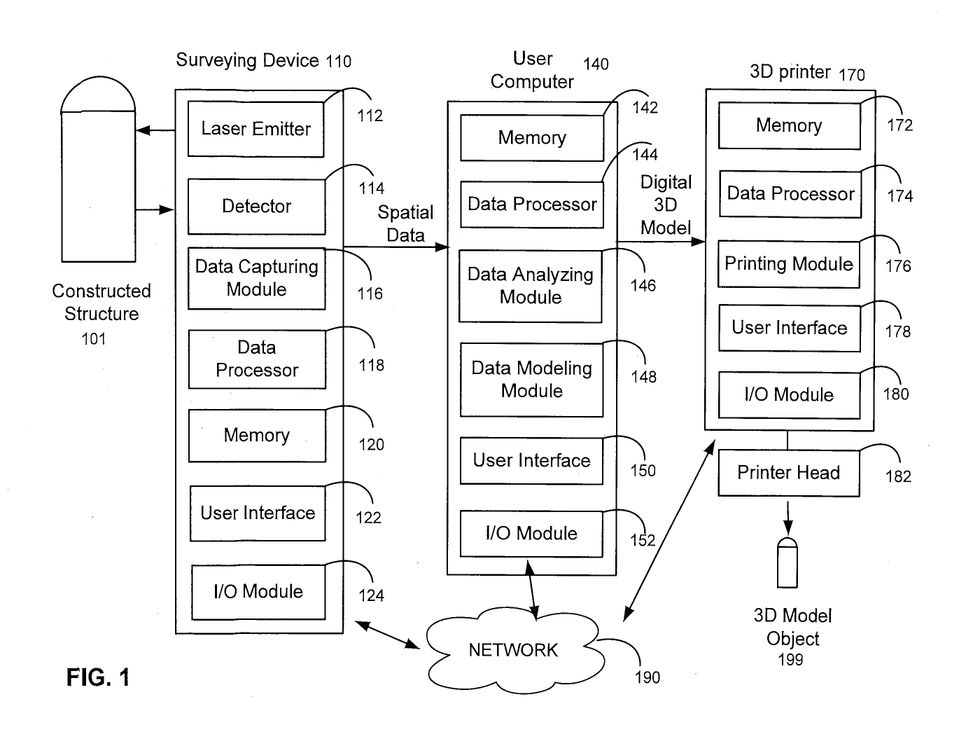

FIG. 1 illustrates block diagrams of a surveying device 110, a user computer 140, and a 3D printer 170 which can be used to survey a constructed structure 101, generate a digital 3D model of the constructed structure, and to produce a 3D model object 199 of the constructed structure in accordance with an embodiment of the present invention. The constructed structure 101 is any man-built structure, as opposed to land or natural or topographic features of an area of land. The constructed structure generally has a housing with an outer surface or a boundary that can be surveyed. For example, the constructed structure can be a building, a house, an industrial plant (e.g., oil refinery), their supporting infrastructure (e.g., water pipes, gas pipes, or others), or any parts thereof. In an embodiment, the constructed structure has a fixed position on earth and is georeferenceable in a real-world coordinate system. Georeferenceable refers to being able to define its existence in physical space, such as establishing its location on the earth (e.g., in terms of a coordinate system and an elevation datum). Thus, each point or a portion of the constructed structure can be mapped and georeferenced in an objective, real-world coordinate system and an elevation datum.

The surveying device 110 is any instrument which can be used to survey a constructed structure to obtain spatial data associated with the constructed structure. The spatial data refers to any data that provides information about location of points, lines, and physical features of a constructed structure in physical space and their dimensional relationships. The spatial data can be analyzed to determine shape, contour, dimensional relationships of various features, orientation, georeference information, and/or elevation information related to physical elements of a constructed structure. Any suitable surveying device can be used to obtain spatial data associated with the constructed structure. For example, in the embodiment illustrated in FIG. 1, the surveying device 110 is a 3D laser scanner. Examples of 3D laser scanners include Leica ScanStation™ manufactured by Leica Geosystems™, Trimble FX™ or GX™ Scanner manufactured by Trimble, other 3D laser scanners from other manufacturers, such as Faro™, Riegl™, Optech™, or the like. The spatial data obtained from a 3D laser scanner is also referred to as scan data or point clouds.

While the embodiment illustrated in FIG. 1 includes the use of a 3D laser scanner as a surveying device, any suitable surveying device that provides spatial data may be used. For example, traditional surveying devices, such as theodolites, total stations, digital levels, survey transits, or the like can be used to survey a constructed structure and to obtain spatial data associated with the constructed structure. A single surveying device or a combination of surveying devices may be used together in embodiments of the present invention.

In the embodiment illustrated in FIG. 1, the surveying device 110, which is a 3D laser scanner, has a laser emitter 112 and a detector 114. A laser beam is emitted from the laser emitter 112 which is reflected off the surface of the constructed structure 101. The reflected light from the constructed structure 101 is captured by the detector 114, generating spatial data (e.g., a point cloud) associated with the constructed structure 101 by determining phase shift or “time-of-flight.” The points in the point cloud each indicate a location of a corresponding point on a surface of the constructed structure. The density of the point cloud captured depends on the range of the scanner from the surfaces being measured: the closer the range, the denser the point cloud.

A user can enter various inputs using a user interface 122, which can result in data transfer through Input/Output (I/O) module 124 and network 190. The information from the user, for example, commands for scanner operation such as a scan rate, a field of view, a desired resolution for the scan, can be received and processed by a data processor 118 and a data capturing module 116. The received and/or processed information can be stored using memory 120 and can be displayed using the user interface 122. The user input provided through the user interface 122 is processed by the data processor 118 and is communicated to the data capturing module 116, which in turn, controls the laser emitter 112 and the detector 114. The user interface 122 can be also used to set up the surveying device, to monitor the scan process, and to view the captured spatial data

The spatial data captured by the detector 114 is stored in memory 120 of the surveying device 110. The memory 120 includes to one or more mechanisms for storing data. The memory may be volatile (e.g., random access memory), non-volatile (e.g., read-only memory), magnetic disk storage media, optical storage media, flash memory devices, and/or other machine or computer-readable media. The machine or computer-readable media may be removable and/or non-removable. The discussion related to memory 120 of the surveying device 110 also applies to memory 142 in the user computer 140 and memory 172 in the 3D printer 170.

An input/output module 124 (also referred to as a communications module) is provided to enable communication between the surveying device 110 and other devices or users. For example, the input/output module can be used to transfer the spatial data stored in the memory 120 to other devices (e.g., a user computer 140) via USB, Ethernet, or through a network 190, which may be the Internet, a local area network, or the like. In some embodiments, the spatial data is stored in a removable data storage (e.g., an external hard drive), which can be transferred to the user computer 140 for further data processing. While not illustrated in FIG. 1, the surveying device 110 may have additional components. These include, for example, a power supply, a GPS receiver, a camera, a video recorder, or the like.

Using the surveying device 110, the constructed structure is typically scanned several times from one or more locations (or using different instruments). Two or more scan datasets are first combined (registered) into one point cloud of the whole constructed structure. In an embodiment, the registration of the multiple point clouds can be the event where the georeferencing occurs. The registered point cloud can be transformed to an external coordinate system (e.g., a real-world coordinate system) and/or an elevation datum using the coordinates of minimum of three well-distributed control points. The control points can be realized by means of special targets placed on or nearby the constructed structure being scanned. Alternatively, the surveying device 110 can be set over a point with known coordinates (e.g., a control point) and back sighting to another known point to measure the orientation (the z-axis is typically referenced to gravity through instrument leveling). Thus, each point in the point cloud can be registered and georeferenced to a specific location in a real-world coordinate system and/or an elevation datum. Since each point in the point cloud represents a point on the surface of a constructed structure, each point on the surface of the constructed structure can be georeferenced as well. Any suitable software can be used for georeferencing and/or registration of point clouds. These include, for example, Trimble Realworks™, Leica Cyclone™, or the like.

In the embodiment shown in FIG. 1, a user computer 140 can be used to analyze the spatial data (e.g., point clouds) obtained by the surveying device 110 and to create a digital 3D model of the constructed structure 101. The user computer 140 has a number of components, including memory 142, a data processor 144, a data analyzing module 146, a data modeling module 148, a user interface 150, and an input/output module 152. These components can interact with one another and with the network 190 to receive the spatial data from the surveying device 110 and to generate a digital file comprising image data of a digital 3D model of the constructed structure 101.

The spatial data associated with the constructed structure obtained from the surveying device 110 can be analyzed using the data analyzing module 146 and the data processor 144. The data analyzing module 146 can analyze the spatial data and convert the data into deliverables. The data analyzing module 146 may be comprised of individual software modules. As an example, the data analyzing module 146 may include a software module that provides tools for aligning point clouds captured from different scanning positions. In another example, the data analyzing module 146 may include a software module that allows a user to use point clouds directly to process them into objects for exporting into CAD and other applications, and to import data from CAD and other applications. In yet another example, the data analyzing module 146 may include a software module that allows extraction of feature (e.g., distances, volumes, or other geometric or physical parameters) and coordinate information (e.g., georeference parameters) from the spatial or point cloud data so that each point can be assigned to a real-world coordinate system and/or an elevation datum. Examples of such software modules include PointCloud™ from Kubit™, Leica Cyclone™, Leica Cloudworx™ from Leica™, Realworks™ from Trimble™, or the like. In FIG. 1, while the data analyzing module 146 is included in the user computer 140, some or all of software modules of the data analyzing module 146 can be included in the surveying device 110.

The user computer 140 can further include the data modeling module 148 which can receive spatial data analyzed by the data analyzing module 146 to generate image data comprising a digital 3D model or other 2D models of the constructed structure (e.g., 2D slices at various elevation levels). The data modeling module 148 can include various functions, such as data editing, segmentation, fitting of geometric primitives (e.g., planes, spheres, cones, cylinders), or the like. In embodiments of the present invention, the data modeling module 148 can include AutoCAD™ (e.g., AutoCAD™ Civil 3D, AutoCAD Plant™, AutoCAD™ software, or the like), or other computer modeling software for the data analysis and conversion. The modeling process results in a digital 3D model of the constructed structure 101, illustrating the surface contour and other geometric features of the constructed structure.

In one implementation, the data modeling module 148 allows incorporation of surveyed and measured real-world intelligence associated with the constructed structure 101 into the generated digital 3D model. As an example, a portion of the digital 3D model may be selected by a user by clicking on the portion. A user can modify the portion of the digital 3D model by inserting or typing one or more geometric markings which represent geometric parameters (e.g., a radius, a height, a width, or the like) associated the corresponding portion of the constructed structure 101. In another example, a portion of the digital 3D model may be selected and modified by the user to include one or more georeference markings which represent georeference parameters (e.g., a position in a real-world 3D coordinate system) associated with a corresponding portion of the constructed structure.

In the embodiment illustrated in FIG. 1, image data comprising a digital 3D model of the constructed structure 101 can be entered into a processor of a 3D printer 170, which in turn, produces a 3D model object 199. As shown in FIG. 1, the 3D printer 170 has a number of components: memory 172 which can receive and store the digital file created by the user computer 140 through an input/output module 180, a data processor 174, a printing module 176, and a user interface 178. The user interface 178 can be used to receive user input and to display functional controls for the printing process. The printing module 176 can receive user input related to functional controls for the printing process, which in turn, can send a command to a printer head 182 for building a 3D model object based on the received image data defining the digital 3D model.

The 3D printer 170 generally uses additive processes, in which a physical model object is created by laying down successive layers of material (e.g., depositing droplets of melted material, powder, or the like through a nozzle) through the printer head 182 until the entire object is complete. The digital file is prepared by the data modeling module 148 of the user computer 140 or the printing module 176 of the 3D printer 170 by slicing the digital 3D model design into hundreds or thousands of horizontal layers. These layers laid by the printer head 182 are joined together or fused automatically to create the final shape of a 3D model object. A 3D model object produced by the 3D printer 170 in accordance with the present invention is therefore a scaled down reproduction of a real-world constructed structure based on accurately surveyed data.

In embodiments of the present invention, any suitable materials, such as thermoplastics, binders, or resins, can be used to create a 3D model object according to embodiments of the present invention. For example, any polycarbonate, polyetherimide, polyphenysulfone, acrylonitrile butadiene styrene, or the like can be used. In some embodiments, color pigments can be added to during the additive process. Any suitable 3D printers, such as Fortus 3D™ protection systems from Stratasys™, can be used in embodiments of the present invention.

While FIG. 1 illustrates an embodiment where a surveying device, a user computer, and a 3D printer are housed in three separate housings, functions performed by the three devices may be integrated into less than three housings or divided into four or more housings of devices to perform the tasks described in embodiments of the present invention.

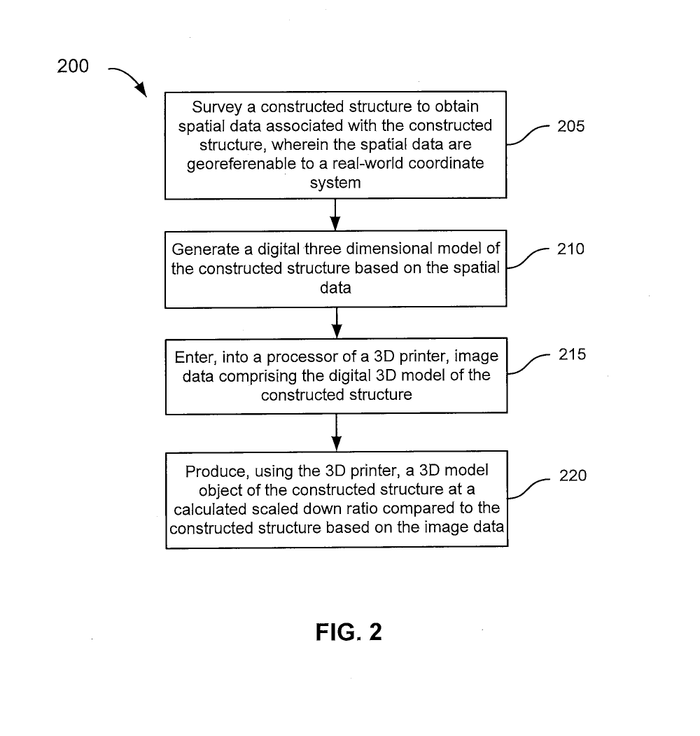

FIG. 2 is a high level flowchart illustrating a method of producing 3D model objects based on surveyed as-built data associated with a real-world constructed structure according to an embodiment of the present invention. Referring to FIG. 2, the method 200 includes surveying a constructed structure to obtain spatial data associated with the constructed structure (205). In embodiments of the present invention, any suitable surveying devices described in relation to FIG. 1 may be used to obtain spatial data associated with the real-world constructed structure. In an embodiment, the constructed structure is affixed to a specific geographical position on the earth, and the constructed structure (and any portion thereof) can be georeferenced according to its position and orientation in a real-world coordinate system and/or an elevation datum.

In one implementation, a 3D laser scanner is used to obtain spatial data associated with a constructed structure. The 3D laser scanner scans a constructed structure and generates spatial data which may be a point cloud, each indicating a location of a corresponding point on a surface of the constructed structure. The point cloud data can be analyzed by the data analyzing module 146 to obtain various information and parameters related to surface, contour, geometric data, color, texture, or other attribute information related to the constructed structure. For example, analyzed parameters can include dimensions such as a length, a width, a height, a radius, a circumference, a volume or angles of portions of the constructed structure. Generally, a constructed structure can be surveyed so that geometric parameters (e.g., dimensions, angles, or the like) obtained from the surveyed spatial data are within ⅛″ (⅛ of an inch or 1/100 of a foot) of actual geometric parameters with at least a 95 percent confidence level.

The spatial data stored in the memory can be analyzed and processed using the data modeling module 148 to generate a digital 3D model of the constructed structure (210). The data modeling module can include any suitable modeling software, such as AutoCAD™, to generate a digital 3D model of the constructed structure on a screen of a computer or other electronic devices. Once the digital 3D model is generated from the spatial data, the dimensionally correct digital 3D model can be viewed from any perspective within the virtual 3D environment. In some embodiments, the digital 3D model can be sliced at various elevation levels to create 2D models that can be used to create floor plans, elevations or sections, labeled with appropriate dimensions for various features of the 2D models. The data defining the digital 3D model or 2D models can be stored in in the memory 142 of the user computer 140.

In one implementation, the digital 3D model generated based on the scan data can be cross referenced and checked against an archived plan. If a blueprint with archived dimensions (such as a radius length and feature degree orientation) exists for a constructed structure, a supplemental digital 3D model can be created based on the archived dimensions of the constructed structure. The digital 3D model based on physically surveyed scan data can be digitally overlaid over the supplemental digital 3D model based on the archived plan by orienting them to the same coordinates and elevation levels. Any discrepancies in geometry or dimensions between the two digital 3D models can be highlighted for a user.

In another implementation, a selected portion of the digital 3D model of the constructed structure can be modified according to a future plan for the selected portion. For example, if an interior of a building is surveyed and a staircase in the building will be replaced, then the digital 3D model of the interior of the building can be modified to remove the staircase. Removing the staircase in the digital 3D model will allow building professionals to better visualize the space available and to design a new staircase suitable for the building. In another example, if an exterior of a house is surveyed and existing windows will be replaced with larger windows, then the digital 3D model of the house can be modified to insert new larger windows. In these embodiments, the digital 3D model incorporates existing as-built data of the surveyed constructed structure which is modified by the future plan for a selected portion of the constructed structure.

In embodiments of the present invention, the data defining the digital 3D model is converted into a printable format which is compatible with a 3D printer. For example, the data is converted into a printable file, such as .STL format. The digital 3D model is sliced for optimum build speed during successive additive layer of material to build a 3D model object. In some embodiments, the digital file can be formatted into a printable file by the 3D printer by the printing module 176.

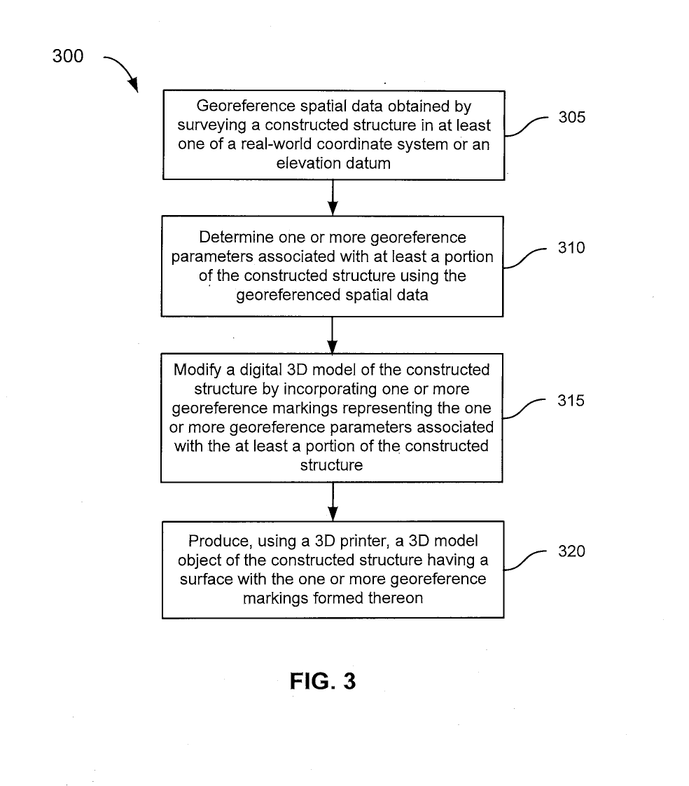

In the method 200, the digital file comprising the image data of the digital 3D model is entered into a 3D printer (215). The image data is data that comprises information to generate a digital 3D or 2D model of a constructed structure on a screen of a computer or other electronic devices. The image data may include additional information such as one or more markings (e.g., geometric markings, georeference markings, or the like) associated with a digital 3D model as described below in relation to FIG. 3. The digital file created by the user computer 140 can be transmitted to the 3D printer via a network, or a computer-readable medium storing the digital file can be inserted into the 3D printer so that the image data can be accessed by the 3D printer. The 3D printer produces a 3D physical object representing the constructed structure at a calculated scaled down ratio compared to the constructed structure in the real world using the digital file (220). The size of the 3D model object can be selected by a user input. The user can input an absolute linear dimension of the 3D model object desired or a scaled down ratio between a constructed structure and its 3D model object.

In some embodiments, a 3D model object comprises a plurality of object pieces, each of which is produced separately using a 3D printer. Using the data modeling module 146, a digital 3D model of the constructed structure can be partitioned as desired. For example, the digital 3D model of the constructed structure is partitioned according to how the constructed structure will be assembled or disassembled in the field. In another example, the digital 3D model of the constructed structure is partitioned according to how different sections of the constructed structure are joined. In yet another example, the digital 3D model of the constructed structure is partitioned according to a future plan for portions of the constructed structure. In an embodiment, separate digital file is created for each partitioned portion of the digital 3D model so that the 3D printer can produce each object piece separately.

The object pieces produced by the 3D printer can be attached to one another to form an integrated 3D model object. A variety of attachment mechanisms or fasteners can be used. For example, magnets can be used to assemble object pieces so that the object pieces are attached to one another with their features oriented in a correct, georeferenced position. In another example, attaching ends of object pieces may have threads that allow the object pieces to attach to one another. In another example, snap fits can be used as an assembly method for assembling the object pieces. Examples of snap fits include taper snaps, a ball and a socket joint, a pen and a barrel, cantilever snap fits, or the like. In some embodiments, dowels may be used to connect different object pieces together. In some embodiments, the object pieces are removably attachable so that they can be assembled, disassembled, and re-assembled as needed.

In one implementation, each object piece can have one or more markings on its outer surface allowing a user to align them together in a correctly surveyed orientation. As an example, each object piece may have a georeference marking “E” embossed at an accurately surveyed location. When a user assembles multiple object pieces together, the user can use the marking on each object piece as a guide in assembling object pieces together such that physical features on the assembled 3D model object are oriented in a correct, georeferenced location.

In an embodiment of the present invention, object pieces can be color coded according to the source of spatial data or a future modification plan associated with each of the object pieces. For example, an object piece which is surveyed using a 3D laser scanner can be produced in a cream color, whereas another object piece which is produced based on archived paper prints are produced in yellow. In another example, object piece which represents a future modification plan can be produced in green. In one implementation, one or more color pigment can be added to the 3D printer prior to the production of each of the object pieces. The color scheme of the 3D model object allows building professionals to immediately visualize the source of spatial data obtained for each piece or the future modification plan for constructed structure.

In another implementation, a kit comprising a 3D model object and a scaled measurement device is provided. The 3D model object is produced at a calculated scaled down ratio of the real-world constructed structure. A scaled measurement device included in the kit has distance markings indicating a scale of the 3D model object in relation to the constructed structure. For example, a distance between adjacent distance markings on a scaled measurement device (and the corresponding distance on a 3D model object) may represent a distance of 1 foot for a constructed structure in the real world. Building professionals can use a scaled measurement device against the 3D model object to determine a linear dimension between two locations of interest on a constructed structure.

FIG. 2 illustrates multiple steps that can be practiced by a single entity or multiple entities. As an example, a surveying company can perform all of the steps shown in FIG. 2. In another example, a surveying company can perform the surveying step (205) and the digital 3D model generation step (210), and a printing company can perform the image data entry step (215), and the 3D model object production step (220). In the example where two parties are performing the steps of FIG. 2, the digital file containing the image data can be transmitted from one party to the other using any suitable methods. For example, a digital file can be mailed, e-mailed, or uploaded to a cloud storage which is accessible by a third party for 3D printing.

It should be appreciated that the specific steps illustrated in FIG. 2 provide a particular method of producing 3D model objects according to an embodiment of the present invention. Other sequences of steps may also be performed according to alternative embodiments. For example, alternative embodiments of the present invention may perform the steps outlined above in a different order, or each step may include multiple sub-steps. Furthermore, one or more steps may be added or removed depending on the particular applications. For example, features described in other figures or parts of the application can be combined with the features described in FIG. 2. One of ordinary skill in the art would recognize many variations, modifications, and alternatives.

FIG. 3 is a high level flowchart illustrating a method of producing a 3D model object imprinted with one or more markings representing relevant, measurable real-world intelligence associated with the constructed structure on the surface of the 3D model object. Referring to FIG. 3, the method 300 includes georeferencing spatial data obtained by surveying a constructed structure to at least one of a real-world coordinate system or an elevation datum (305). To georeference spatial data means to establish coordinates and elevations on precise locations on a physical element on a structure. The coordinates systems establish the horizontal position while the elevation datum establishes the vertical position. Therefore, by georeferencing points in the spatial data (e.g., in a point cloud), precise locations of physical elements on a structure can be established in terms of a known, real-world coordinate system and/or an elevation datum (sometimes referred to as a vertical datum).

A real-world coordinate system defines how georeferenced spatial data relates to real locations on the earth's surface. Coordinate systems can be based on public datums such as the California Coordinate system or private datums such as an established industrial plant datum. An elevation datum is used for measuring the elevation of points on the Earth's surface. Elevation datums can be established from public datums such as the National Geodetic Datum or private datum such as industrial plant datums and benchmarks. For example, elevations can be cited in height above sea level (e.g., Mean Sea Level). In another example, in a private, industrial plant datum, an elevation level is typically based from an existing structure on the plant.

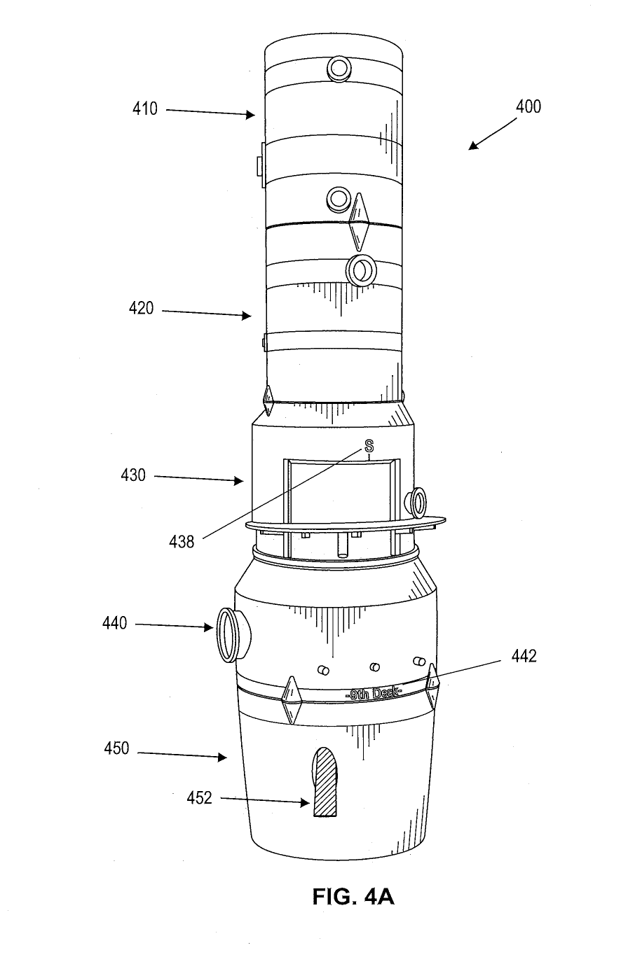

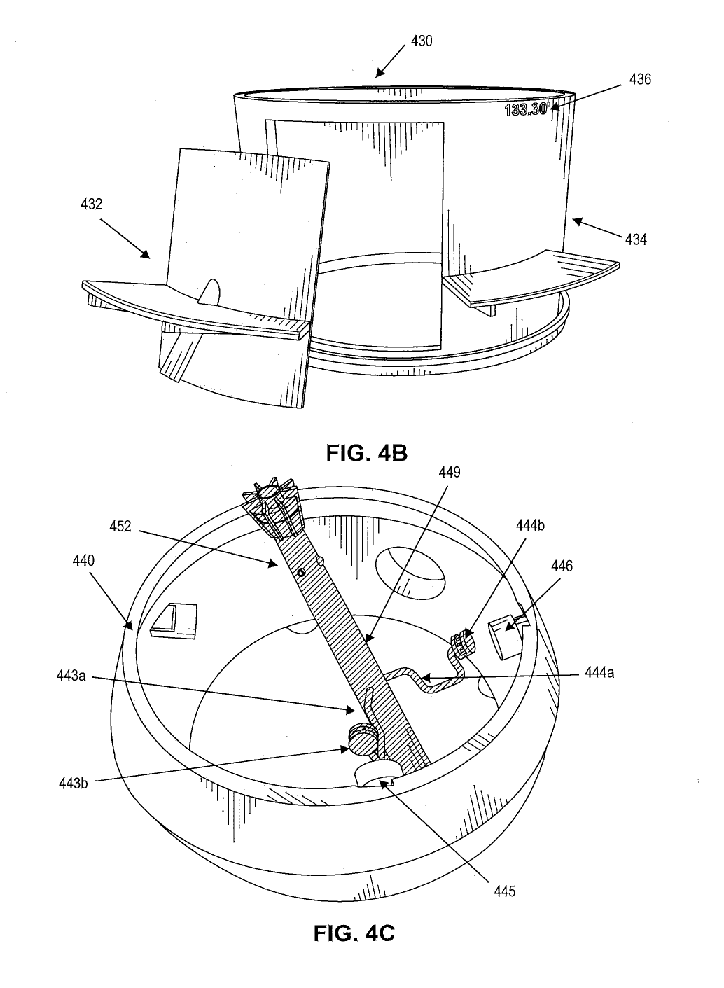

In embodiments of the present invention, any suitable real-world coordinate systems and elevation datums can be used to define a position of points in the spatial data. Examples of a real-world coordinate system include a global coordinate system, a national coordinate system, a state coordinate system (e.g., California Coordinate System NAD 83 and NAD 88), a local plant grid system, or the like. Examples of an elevation datum include an elevation above Mean Sea Level, a gravity based geodetic datum NAVD88 used in North America, NAD 27, or the like. Any one of these real-world coordinate systems and elevation datums can be selected to describe a location of a point on the spatial data (which corresponds to a point on the surveyed surface of a constructed structure). As an example, the location of a coker unit itself and physical features of the coker unit shown in FIG. 4A can be described according to a private plant datum of an oil refinery, which has its own private, local coordinate system and elevation datum.

Referring to FIG. 3, the method 300 also includes determining one or more georeference parameters associated with at least a portion of the constructed structure using the georeferenced spatial data (310). As used herein, a portion of a constructed structure refers to a point, a line, an area or section of the constructed structure. A georeference parameter can be any measured value obtainable from the georeferenced spatial data. A georeference parameter can provide information related to a geographical position or coordinates on the earth (e.g., latitude and longitude), an elevation level, and/or a bearing and orientation associated with a portion of a constructed structure. Any suitable software can be used for determining georeferencing parameters. These include, for example, Trimble™ Realworks™ or Leica™ Cyclone™.

Generally, a constructed structure can be surveyed by a professional surveyor so that georeference parameters (e.g., an elevation, orientation, position, coordinates, or the like) obtained from the surveyed spatial data are within ⅛″ (⅛ of an inch or 1/100 of a foot) of actual georeference parameters of a constructed structure with at least a 95 percent confidence level. In an embodiment, a professional surveyor can provide a certification statement that the positional accuracy of the location of any point on a survey relative to a defined datum is given at the 95 percent confidence level.

A georeference parameter can be expressed in terms of any selected real-world coordinate system or an elevation datum. As an example, a marking 436 on a portion of a coker unit model object shown in FIG. 4B indicates an elevation of 133.30 feet according to a private plant datum of an oil refinery. Alternatively, a marking 442 on the coker unit shown in FIG. 4A indicates an elevation in terms of a deck level (i.e., 9^{th} Deck) according to the numbering of deck platforms used in the oil refinery. Similarly, the peak of the center of the coker unit shown in FIG. 4A can be described as having coordinates Northing=3993.4750; Easting=601.6745; and Elevation=276.0518 according to a private plant datum of an oil refinery.

A georeference parameter can also include an orientation or bearing associated with a portion of a constructed structure. The orientation refers to a location or a position relative to points of the compass. Examples of an orientation associated with a portion of a constructed structure may be northerly, southerly, easterly, westerly, northeasterly, northwesterly, southeasterly, or southwesterly relative to points of the compass. The bearing can refer to direction (e.g., angular direction) measured from one position to another using the compass. For example, for a cylindrical vessel, if Point B on the outer surface of the vessel is located exactly southeast of Point A, which is the center of the vessel, the bearing from Point A to Point B is S 45° E. The angle value in a bearing can be specified in the units of degrees (and minutes and seconds), mils, or the like.

The values for various georeference parameters can be obtained using any suitable modeling software. The digital 3D model of a constructed structure is generated based on surveyed spatial data using a modeling software (e.g., AutoCAD™) as described above in relation to FIGS. 1 and 2. For example, georeferencing can occur in AutoCAD™ by surveying certain precise features and rotating and translating a digital 3D model to the surveyed locations that have coordinates and elevations on them. Typically, georeferencing can be achieved when there are at least three locations on the physical structure that have the horizontal and vertical features. As such, georeference, geometric, or other parameters associated with the constructed structure are embedded in the image data comprising the digital 3D model. If desired, these parameters can be queried by a user using the modeling software. After the digital 3D model of the constructed structure is generated on the computer screen, any portion of the digital 3D model can be queried by a user to determine one or more georeference parameters associated at least a portion of the constructed structure. As an example, a user can click on a portion of the digital 3D model on the computer screen and query its elevation level. In another example, a user can click on another portion of the digital 3D model displayed on the screen and request its coordinate information. In some embodiments, a user may request an orientation (e.g., north, south, east, and west) or bearing associated with a portion of the digital 3D model of a constructed structure.

Referring to FIG. 3, the method includes modifying a digital 3D model of the constructed structure by incorporating one or more georeference markings representing the one or more georeference parameters associated with the at least a portion of the constructed structure (315). Modifying the digital 3D model refers to changing the digital 3D model shown on the computer screen to include labels or markings representing the one or more georeference parameters. For example, a user can select and click on a portion of the digital 3D model on the screen and request information related to its elevation level or other coordinates. In an embodiment, a user may input (e.g., by typing on the screen) one or more georeference markings on the selected portion of the digital 3D model based on the information. In another embodiment, a user can select and click on a portion of the digital 3D model on the screen and request the portion be labeled or marked automatically with one or more georeference parameters. Thus, a modified digital 3D model is a digital 3D model of the constructed structure selectively labeled or marked with relevant real-world intelligence.

A georeference marking used to represent a georeference parameter can include one or more of numbers, letters, or symbols. For example, an elevation level of 133.08 feet may be represented by any one of the following georeference markings: “133.08 feet,” “133.08′,” “an elevation of 133.08′,” or the like. In another example, a portion of the digital 3D model facing south direction may be labeled with any of the following georeference markings: “S,” “south,” “South,” “S” or the like. In yet another example, a portion of the digital 3D model facing southeasterly may be labeled with a georeferencing marking, “SE 41°31′22″.” Any suitable markings can be used to represent georeference parameters as long as surveyors and other building professionals can understand the meaning of the georeference markings.

A georeference marking can be incorporated or imprinted into the digital 3D model in a number of different ways. For example, a georeference marking can be embossed onto the outer surface of the digital 3D model. For example, a georeference marking for south orientation, “S,” may be incorporated onto the outer surface of the digital 3D model with a letter “S” raised outwardly above from its surface. Alternatively, a georeference marking “S” may be incorporated onto the outer surface of the digital 3D model by embossing the letter “S” by indenting or depressing the letter inwardly from the surface of the digital 3D model.

Using the modified digital 3D model, a 3D printer can produce a 3D model object of the constructed structure with georeference markings formed on the surface of the 3D model object (320). In the method, the image data of the digital 3D model modified with georeference markings is entered into a processor of a 3D printer. Since a georeference marking is already incorporated in the digital 3D model, the successive layering of the modified digital 3D model by the 3D printer automatically forms the georeference marking exactly on the same location as on the digital 3D model. In an embodiment of the present invention, as the georeference markings are produced during the 3D printing process, the markings are made of the same material as the rest of the 3D model object.

The physical appearance of a georeference marking on a 3D model object will depend on how the georeference marking is incorporated in the digital 3D model. For example, if the georeference marking is embossed with the marking being raised (i.e., outward) above the surface of the digital 3D model, then the georeference marking in the 3D model object produced by the 3D printer will appear embossed with the marking being raised above the surface of the 3D model object. If the georeference marking is embossed by indenting or depressing it below the surface of the digital 3D model, then the georeference marking in the 3D model object produced by the 3D printer will appear indented and formed below the surface of the 3D model object.

While FIG. 3 is described in reference to georeference markings, a digital 3D model (and the corresponding 3D model object) can be modified to incorporate other real-world intelligence relevant to a constructed structure. For example, any geometric parameter, such as a dimension of a portion of the constructed structure can be incorporated into the digital 3D model. For example, a digital 3D model of a cylindrical vessel can be modified to incorporate one or more geometric markings representing a vessel diameter, a height, a volume, or the like. In another example, clearance dimensions (e.g., a gap between an inner surface of a vessel and an outer surface of an inner component) can be incorporated into a digital 3D model. In yet another example, a physical parameter, such as a center of gravity, for a constructed structure can be determined based on geometric parameters, materials used for construction, and a distribution of its weight. A physical marking representing the physical parameter may be incorporated into an appropriate location in the digital 3D model.

Any discussions related to georeference markings described above also apply to incorporating geometric or other markings onto the surface of the digital 3D model or the 3D model object produced by the 3D printer. For example, a geometric marking can include any one or combination of numbers, letters, and symbols. For example, a vessel having a radius of 10 feet as a geometric parameter can be presented by any one of the following markings: “r=10.00′,” “radius—10.00 ft,” or the like. A user can select to have geometric marking embossed onto the surface of the digital 3D model so that the marking is raised above the surface of the digital 3D model or indented below the surface of the digital 3D model. A 3D printer can incorporate the geometric markings in a 3D model object according to how they are incorporated in the digital 3D model.

The georeference, geometric, and other markings incorporated on the surface of a 3D model object provide useful, relevant, and measured real-world intelligence of the constructed structure. The markings provide an immediate visual aid for building professionals in planning a future project for the constructed structure.

It should be appreciated that the specific steps illustrated in FIG. 3 provide a particular method of producing 3D model objects according to an embodiment of the present invention. Other sequences of steps may also be performed according to alternative embodiments. For example, alternative embodiments of the present invention may perform the steps outlined above in a different order, or each step may include multiple sub-steps. Furthermore, additional steps may be added or removed depending on the particular applications. For example, features described in other figures or parts of the application can be combined with the features described in FIG. 3. One of ordinary skill in the art would recognize many variations, modifications, and alternatives.

FIG. 4A illustrates an example of a 3D model object produced according to an embodiment of the present invention. The 3D model object 400 shown in FIG. 4A is a coker unit used in an oil refinery to process crude oil to refined gasoline. A coker unit in the oil refinery was scanned using Leica ScanStation. The scan data generated by Leica ScanStation was analyzed using Leica software to determine geometric and georeference parameters. The scan data was transferred to AutoCAD™ software to generate a digital 3D model of the coker unit. The image data comprising the digital 3D model was entered into a processor of a 3D printer, Fortus from Stratasys, to produce a 3D model object of the coker unit shown in FIG. 4A.

As shown in FIG. 4A, the 3D model object representing the coker unit is comprised of a plurality of object pieces 410, 420, 430, 440, and 450, which are assembled together through snap fits. The object pieces 410, 420, 430, 440, and 450 were printed separately using a 3D printer. Each object piece shown in FIG. 4A was built vertically by the 3D printer based on digital 2D horizontal slices of the digital 3D model of the coker unit. The 3D model object was divided into object pieces 410, 420, 430, and 440, and 450 so that they can be disassembled and re-assembled according to how the coker unit will be disassembled and re-assembled in the field. The object piece 450 has an internal component 452 extending outward through a hole. The internal component 452 will be described in further detail in relation to FIG. 4C below. Dissembling one or more coker unit object pieces allows visualization of all of the internal components within the coker unit 3D model object.

The object piece 430 has a marking, “S” 438, which represents a true southerly surveyed direction of the coker unit. The object piece 440 has a marking, “9^{th} deck” 442, which represents the true surveyed elevation level that corresponds to the 9^{th} deck of the plant platform level. These markings on the surface of the 3D model object provide real-world intelligence about the constructed structure on the site.

FIG. 4B illustrates an enlarged view of the object piece 430 shown in FIG. 4A. The object piece 430 represents one segment of the coker unit, which includes a door sheet 432. The door sheet 432 can be removably attached to the rest of the object piece 434. The door sheet 432 and the rest of the object piece 434 were separately produced using a 3D printer. The object piece 434 has a georeference marking 436 indicating that the elevation level associated with the top edge of the door sheet 452 is at 133.30 feet according to a private plant datum of an oil refinery.

The real-world coker unit in the field does not have a corresponding door sheet shown in FIG. 4B. The door sheet was initially incorporated into a digital 3D model to assist building professionals to visualize whether old internal components can be removed through the door sheet. An appropriate door sheet size was determined based on the size of internal components. Instead of simulating whether old internal components can be removed through the door sheet in the virtual environment, the 3D model object pieces allow building professionals to physically manipulate the model object pieces to test clearance. By testing clearance through the door sheet using the model object pieces, the building professionals can gain confidence and move forward with the future project.

FIG. 4C illustrates an enlarged view of the object piece 440 of the 3D model object of a coker unit shown in FIG. 4A and an internal component model object 441 (also referred to as “an internal component”) which represents a scouring coke transfer line inside the coker unit. The internal component 452 has two arms 443a and 444a extending from a body 449 of the internal component 452. Distal ends 443b and 444b of the arms are shaped such that they can fit into cups 445 and 446 disposed on the internal surface of the object piece 440. The cups 445 and 446 have one set of magnets inside the cups as fasteners. The distal ends 443b and 444b have another set of magnets as fasteners. The magnets at the distal ends 443b and 444b have a reverse polarity to the exposed side of the magnets in the cups 445 and 446. The internal component 452 with magnets are configured such that features of the internal component 452 are oriented in a correct, georeferenced location inside the object piece 440, as the corresponding internal component is oriented and positioned in the coker unit in the real world.

In the embodiment shown in FIG. 4C, the internal component 452 is colored differently from the rest of the object piece 440. The internal component was created based on 2D archived drawings which were uploaded to modeling software to generate a digital 3D model, from which the internal component was produced using a 3D printer. The color coding of different 3D model object pieces allows building professionals to visualize a source of information or techniques used to create the 3D model object pieces.

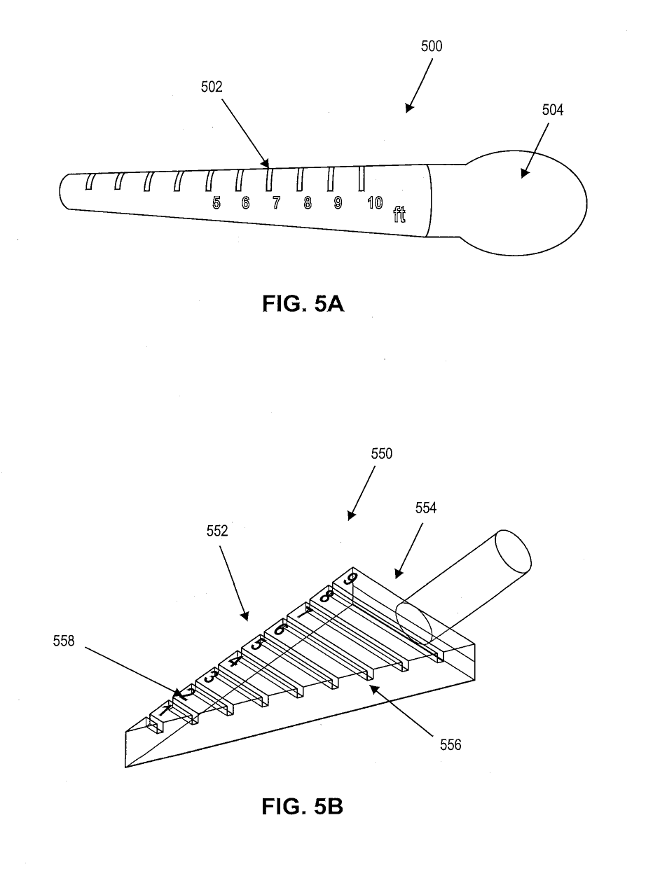

FIGS. 5A and 5B illustrate two different scaled measurement devices that can be used to measure dimensions on the 3D model object representing the coker unit shown in FIG. 4A. A scaled measurement device can be provided as a reference tool in a kit along with a 3D model object. The scaled measurement devices shown in FIGS. 5A and 5B were produced using a 3D printer at the same scale size as the 3D model object shown in FIG. 4A. A scaled measurement device for one 3D model object may be sized and scaled differently than for another 3D model object depending on the calculated scaled down ratio of a 3D model object compared to its corresponding constructed structure.

As an illustration, if a 3D model object is produced at a relatively small scale (e.g., at a calculated scaled down ratio of 1:100 compared to the size of a constructed structure), then a scaled measurement device is produced at the same scaled down ratio. For example, a distance between two adjacent scale markings on the scaled measurement device may be marked as being as 1 foot apart when the actual distance between the two scale markings on the scaled measurement device itself is 1/100 of a foot. Thus, a scaled measurement device is scaled so that it can be used to measure dimensions on a 3D model object and to determine corresponding dimensions on a constructed structure in the real world without further calculation or conversion of units.

A scaled measurement device 500 (also referred to as a probe scale) shown in FIG. 5A has scale or distance markings 502 on one side of the scale probe. The probe scale has graduated stick like scale for measuring along a 3D model object and for establishing a distance in foot. It can be used to measure depth or dimensions of two locations along the 3D model object. FIG. 5B illustrates another type of scaled measurement device 550 (also referred to as a wedge scale) which has two sides 552 and 554 which meet at a right angle. The top portion of the wedge scale has scale markings 556 and numerals 558 representing distance in feet, indicating a scale of the 3D model object in relation to the constructed structure in the real world. The wedge scale is particularly useful in determining clearance or measuring a gap in a 3D model object.

Any of the software components or functions described in this application, may be implemented as software code to be executed by a processor using any suitable computer language such as, for example, Java, C++ or Peri using, for example, conventional or object-oriented techniques. The software code may be stored as a series of instructions, or commands on a computer readable medium, such as a random access memory (RAM), a read only memory (ROM), a magnetic medium such as a hard-drive or a floppy disk, or an optical medium such as a CD-ROM. Any such computer readable medium may reside on or within a single computational apparatus, and may be present on or within different computational apparatuses within a system or network.

The above description is illustrative and is not restrictive. Many variations of the invention will become apparent to those skilled in the art upon review of the disclosure. The scope of the invention should, therefore, be determined not with reference to the above description, but instead should be determined with reference to the pending claims along with their full scope or equivalents.

One or more features from any embodiment may be combined with one or more features of any other embodiment without departing from the scope of the invention.

A recitation of “a,” “an,” or “the” is intended to mean “one or more” unless specifically indicated to the contrary.

It should be understood that the present invention as described above can be implemented in the form of control logic using computer software in a modular or integrated manner. Based on the disclosure and teachings provided herein, a person of ordinary skill in the art will know and appreciate other ways and/or methods to implement the present invention using hardware and a combination of hardware and software.

What is claimed is:

1. A method for producing three dimensional model objects, the method comprising:
entering, into a processor of a three dimensional printer, image data comprising a digital three dimensional model of a constructed structure wherein the digital three dimensional model was generated based on spatial data obtained by surveying the constructed structure, wherein the constructed structure is georeferenceable in a real-world coordinate system; and
producing, using the three dimensional printer, a three dimensional model object of the constructed structure at a calculated scaled down ratio compared to the constructed structure based on the image data.

2. The method of claim 1,
wherein the image data comprising the digital three dimensional model of the constructed structure was modified with one or more georeference markings representing one or more georeference parameters associated with at least a portion of the constructed structure,
wherein the one or more georeference parameters were determined by georeferencing the spatial data to at least one of the real-world coordinate system and an elevation datum, and
wherein the three dimensional model object has a surface and the one or more georeference markings are formed on the surface.

3. The method of claim 1,
wherein the image data comprising the three dimensional model of the constructed structure was modified with one or more geometric markings representing one or more geometric parameters associated with at least a portion of the constructed structure,
wherein the one or more geometric parameters associated with the at least a portion of the constructed structure were determined using the spatial data, and
wherein the three dimensional model object has a surface and the one or more geometric markings are formed on the surface.

4. The method of claim 1, the method further comprising:
surveying the constructed structure to obtain the spatial data associated with the constructed structure; and
generating the image data comprising the digital three dimensional model of the constructed structure based on the spatial data.

5. The method of claim 2, the method further comprising:
georeferencing the spatial data to at least one of the real-world coordinate system and an elevation datum;
determining, using the georeferenced spatial data, the one or more georeference parameters associated with the at least a portion of the constructed structure in relation to at least one of the real-world coordinate system or the elevation datum; and
modifying the image data comprising the digital three dimensional model of the constructed structure by incorporating, in the digital three dimensional model, the one or more georeference markings representing the one or more georeference parameters associated with the at least a portion of the constructed structure.

6. The method of claim 3, the method further comprising:
determining the one or more geometric parameters associated with at least a portion of the constructed structure using the spatial data; and
modifying the image data comprising the digital three dimensional model of the constructed structure by incorporating, in the digital three dimensional model, the one or more geometric markings representing the one or more geometric parameters associated with the at least a portion of the constructed structure.

7. The method of claim 2 wherein the one or more georeference parameters include at least one of a compass orientation, a latitude, a longitude, a set of coordinates, or an elevation level associated with the at least a portion of the constructed structure in relation to the at least one of the real-world coordinate system and the elevation datum.

8. The method of claim 3 wherein the one or more geometric parameters include at least one of a length, a width, a height, a diameter, a radius, an angle, or a volume associated with the at least a portion of the constructed structure.

9. The method of claim 1 wherein the constructed structure is surveyed by a three dimensional laser scanner to obtain the spatial data associated with the constructed structure.

10. The method of claim 1,
wherein the image data comprising the three dimensional model of the constructed structure was modified with a physical marking representing a location of center of gravity for the constructed structure; and
wherein the three dimensional model object has a surface and the physical marking are formed at a selected location on the surface of the three dimensional model object which corresponds to the location of center of gravity for the constructed structure.

11. The method of claim 5 wherein the determined one or more georeference parameters associated with the at least a portion of the constructed structure are within ⅛ of an inch of actual georeference parameters of the constructed structure with at least a 95 percent confidence level.

12. The method of claim 6 wherein the determined one or more geometric parameters associated with the at least a portion of the constructed structure are within ⅛ of an inch of actual geometric parameters of the constructed structure with at least a 95 percent confidence level.

13. The method of claim 1 wherein the image data is a primary image data and wherein the digital three dimensional model is a primary digital three dimensional model, the method further comprising:
generating a supplemental image data comprising a supplemental digital three dimensional model of the constructed structure based on a paper plan which includes a two dimensional drawing and dimensions associated with the constructed structure;
comparing the primary digital three dimensional model generated from the spatial data obtained by surveying the constructed structure and the supplemental digital three dimensional model generated from the paper plan; and
highlighting a discrepancy between the primary image data and the supplemental image data.

14. The method of claim 1 wherein the three dimensional model object includes a plurality of object pieces which are removably attachable to form the three dimensional model object.

15. The method of claim 14 wherein each of the plurality of the object pieces is color coded according to a source of spatial data or a future modification plan for the each of the plurality of the object pieces.

16. The method of claim 1 wherein the three dimensional model object is a first three dimensional model object, the method further comprising:
producing, using the three dimensional printer, a second three dimensional model object of an inner component which is positioned inside of the constructed structure, wherein the inner component has a predetermined position and orientation with respect to the constructed structure, and wherein the second three dimensional model object is configured to be removably fastened inside of the first three dimensional model object.

17. The method of claim 16,
wherein the first three dimensional model object of the constructed structure has an inner surface comprising a plurality of first fasteners disposed on the inner surface,
wherein the second three dimensional model object of the inner component has a plurality of second fasteners disposed thereon, and
wherein the plurality of first fasteners and the plurality of second fasteners are configured to fasten to one another so that the second three dimensional model object has the predetermined position and the orientation with respect to the first three dimensional model object of the constructed structure.

18. A three dimensional model object produced by the method of claim 1.

19. A kit comprising:
a three dimensional model object produced by the method of claim 1; and
a scaled measurement device which has distance markings indicating a scale of the three dimensional model object in relation to the constructed structure.

20. A method for producing three dimensional model objects, the method comprising:
surveying a constructed structure to obtain spatial data associated with the constructed structure;
generating image data comprising a digital three dimensional model of the constructed structure based on the spatial data; and
transmitting the image data to produce a three dimensional model object of the constructed structure at a predetermined scaled down ratio compared to the constructed structure based on the image data.
